(19) United States
(12) Patent Application Publication
(10) Pub. No.: US 2005/0183885 A1
(43) Pub. Date: Aug. 25, 2005

(54) Conducting structure of a multi-layers IC board

(76) Inventor: Wen-Ling Lo, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/780,653

(22) Filed: Feb. 19, 2004

(51) Int. Cl. H05K 7/06

(52) U.S. Cl. 174/261; 174/265

(57) ABSTRACT

The invention relates to a conducting structure of a multi-layers IC board, which includes conducting rod being received in aperture of the IC board to obtain an effective connection and conduction. And the conducting wire is placed horizontally on the IC board, which has its ending pin and annular metal ring to contact with two apertures respectively and to be welded thereon for perfect conduction and smaller assembled volume.

### FIELD OF THE INVENTION

The present invention relates to an improvement of a conducting structure of a multi-layers IC board, which can conduct each layer of IC board effectively and decreases the combined volume of the assembly.

### BACKGROUND OF THE INVENTION

It is known that many new invention of technology is designed to be lighter and smaller for easy carriage and use. Hence, multi-layers IC board has been developed for application. It is known that a conducting wire (1) is used to conduct every layers of the IC board (2), as shown in FIG. 1 to 4. The conducting wire (1) has its annular metal ring (12) to connect with an extended pin (13). The extended pin (13) and the ending pin (11) of the wire (1) are inserted into two neighborhood apertures (21) of the multi-layers IC board (2) and are welded for firm connection and conduction. But by the said method of connection between the pins and the IC board, the welding can not completely filled the whole aperture (21) that remains space therein, as shown in FIG. 2. So the conducting effect is not good. Moreover, the conducting wire (1) is perpendicular to the IC board (2) that occupies a large volume even the wire (1) is bent as in FIG. 4.

### SUMMARY OF THE INVENTION

The present invention is to provide a conducting structure of a multi-layers IC board to overcome the drawback of the prior art and to decrease the assembled volume of the wire and the IC board. Now, accompanying with the following drawings, the character of the present invention will be described here and after.

### BRIEF DESCRIPTION OF THE DRAWINGS

FIG. 1 is an exploded perspective view showing a conventional conducting wire and a multi-layers IC board.

FIG. 2 is an assembled perspective view of FIG. 1.

FIG. 3 is a perspective view of FIG. 2 after being welded.

FIG. 4 is across-sectional plan view of FIG. 3.

FIG. 5 is an exploded perspective view showing a conducting wire and a multi-layers IC board according to the present invention.

FIG. 6 is an assembled perspective view of FIG. 5.

FIG. 7 is a perspective view of FIG. 6 after being welded.

FIG. 8 is across-sectional plan view of FIG. 7.

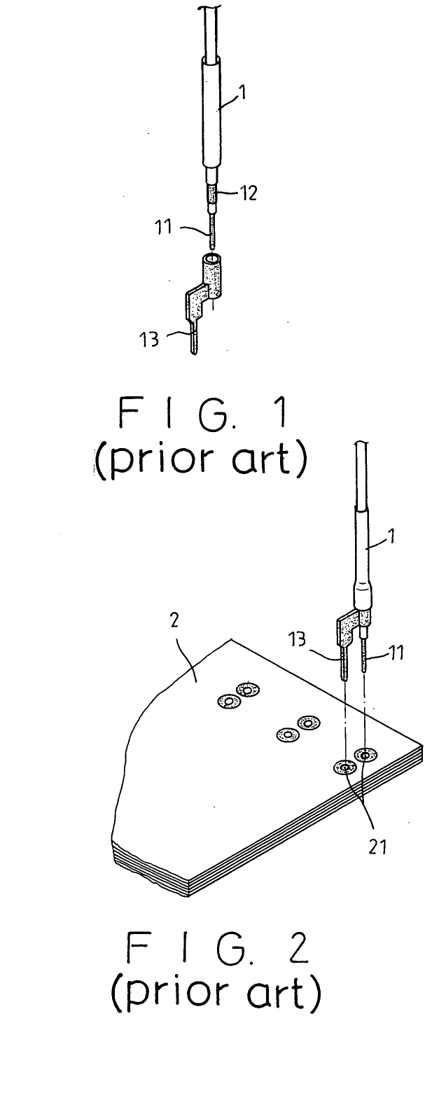

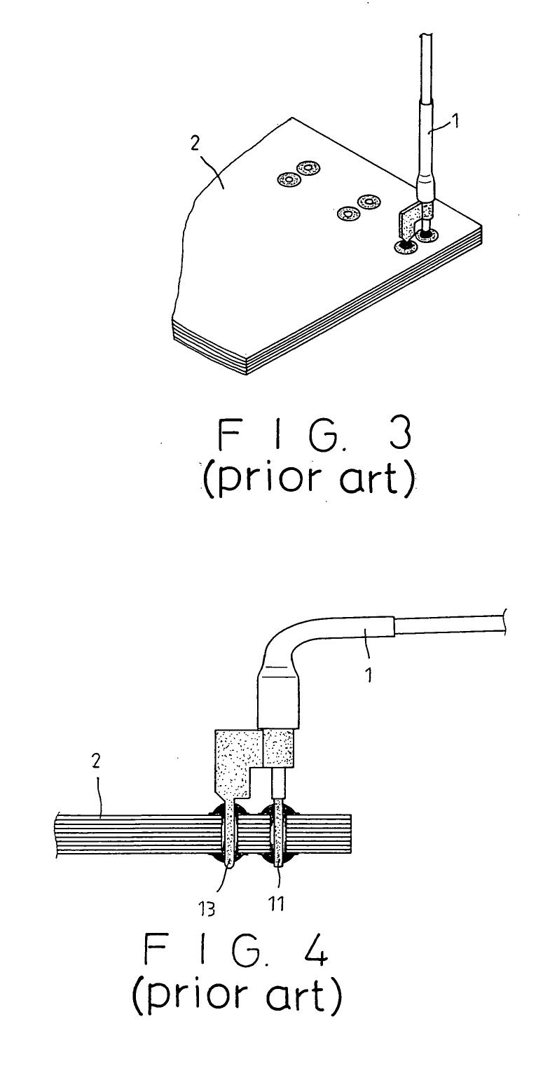

### DETAILED DESCRIPTION OF THE PREFERRED EMBODIMENT

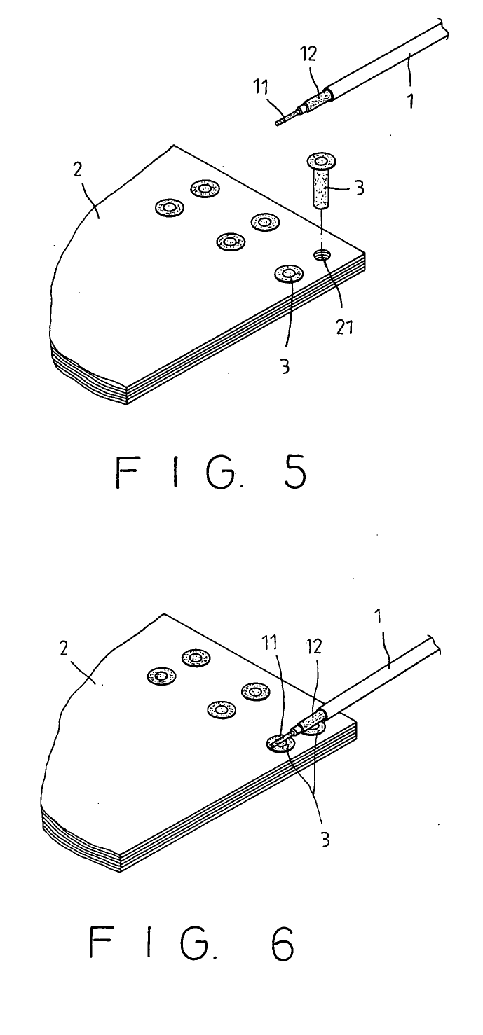

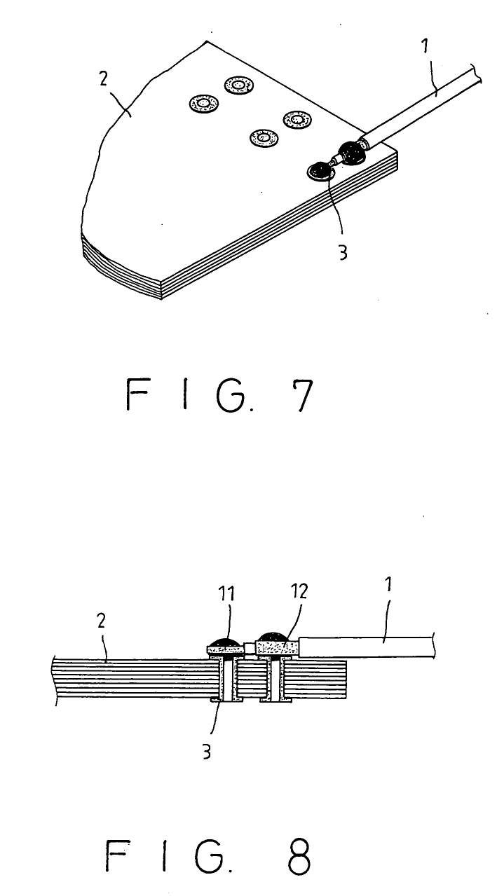

Referring to FIG. 5 to 8, the present invention includes a conducting rod (3), which is received in an aperture (21) of a multi-layers IC board (2). Hence, the conducting rod (3) can contact with each layer of the IC board effectively to provide certain conducting purpose therebetween. Each aperture (21) is provided with a conducting rod (3).

The conducting wire (1) is placed on the IC board (2) horizontally that makes its ending pin (11) and annular metal ring (13) contact with two neighborhood conducting rods (3) respectively. Then the wire (1) can be welded on the board (2) to obtain a firm connection.

Accordingly, the rod (3) is effectively conductive with each layer of the IC board (2) and the pin (11) and the metal ring (13) are capable of being connected with the rod (3) in secure. It is found that the conduction provided by the present invention will be better than the prior art. Furthermore, the conducting wire (1) is placed on the IC board (2) directly that occupies a smaller volume for effective application and improvement.

1. A conducting structure of a multi-layers IC board including a conducting wire and a conducting rod being received in each aperture of the IC board, wherein the rod is conducted with each layer of the IC board, and the conducting wire being placed on the board to have its ending pin and annular metal ring contact with two neighborhood apertures and be welded together for effective conduction.
